(19) United States
(12) Patent Application Publication
(10) Pub. No.: US 2007/0290226 A1
(43) Pub. Date: Dec. 20, 2007

(54) Method for producing a semiconductor arrangement, semiconductor arrangement and its application

(76) Inventors: Juergen Berntgen, Bad Rappenau (DE); Franz Dietz, Untereisesheim (DE); Michael Graf, Leutenbach (DE); Stefan Schwantes, Heilbronn (DE)

Correspondence Address: MCGRATH, GEISSLER, OLDS & RICHARDSON, PLLC, P.O. BOX 1364, FAIRFAX, VA, 22038-1364, US

(21) Appl. No.: 11/806,081

(22) Filed: May 29, 2007

Related U.S. Application Data
(60) Provisional application No. 60/811,780, filed on Jun. 8, 2006.

(30) Foreign Application Priority Data
May 26, 2006 (DE) DE102006024 495.8

(51) Int. Cl. H01L 29/74

(52) U.S. Cl. 257/147

(57) ABSTRACT

A semiconductor arrangement for an integrated circuit is provided that includes a first region in which a number of components are formed, a second region, a buried insulating layer for vertically insulating the first region, an insulating structure, which is formed between the first region and the second region for laterally insulating the first region from the second region. The insulating structure can have a trench structure with a dielectric and a conductor structure with a semiconductor material. Whereby the trench structure borders on the buried insulating layer, and the conductor structure is designed to conductively connect the first region to the second region.

This nonprovisional application claims priority to German Patent Application No. DE 102006024495, which was filed in Germany on May 26, 2006, and to U.S. Provisional Application No. 60/811,780, which was filed on Jun. 8, 2006, and which are both herein incorporated by reference.

### BACKGROUND OF THE INVENTION

1. Field of the Invention

The present invention relates to a method for producing a semiconductor arrangement, a semiconductor arrangement, and its application.

2. Description of the Background Art

In producing integrated circuits, wafers are used which typically include a monocrystalline material such as silicon or germanium, or mixed crystals such as gallium arsenide.

In order to insulate a component in a vertical direction, so-called SOI (silicon on insulator) or SOS (silicon on sapphire) substrates are used, for example. The vertical direction here means a direction perpendicular to a surface of the wafer. The wafer has, for example, a layer sequence of silicon/silicon dioxide/silicon, so that the two silicon layers are insulated from one another by the silicon dioxide layer.

Moreover, it is possible to insulate a component in the lateral direction. A lateral direction here means a direction along the surface of the wafer. Consequently, every lateral direction is perpendicular to the vertical direction. A structure called a deep trench can be used for insulating in the lateral direction. It is etched into the silicon layer in which the components are formed. One or more components can be enclosed by a deep trench in order to insulate them laterally from other components. In this context, this deep trench constitutes one possible form of a lateral insulating structure.

### SUMMARY OF THE INVENTION

It is therefore an object of the present invention to provide a semiconductor arrangement that has a further developed insulating structure.

Accordingly, a semiconductor arrangement having a first region is provided, wherein a number of components are formed in the first region. For example, a high-voltage JFET or an ESD (electrostatic discharge) structure can be formed in the first region.

In addition, the semiconductor arrangement has a second region in which low-voltage components such as, e.g., CMOS structures, can be formed. According to the invention, this second region is to be insulated from the first region, for example in order to be able to use different components having significantly different breakdown voltages in the two regions. It is also possible to provide a high-voltage component in the first region and another in the second region, which operate a full bridge with different voltages, for example.

The semiconductor arrangement can have a buried insulating layer for vertically insulating the first region. This buried insulating layer preferably extends at least below the first region and below the insulating structure. Moreover, the buried insulating layer can additionally extend below one or more subregions of the semiconductor arrangement or over the entire area of the wafer. In this regard, the buried insulating layer advantageously permits insulation from a conductive substrate or from components formed below the insulating layer. Such a buried layer can also be designated as a SOI structure or as a SOS structure.

The semiconductor arrangement has an insulating structure that is formed between the first region and the second region for laterally insulating the first region from the second region. This lateral insulation by the insulating structure makes it possible for the first and second regions to advantageously be designed to be laterally offset from one another on the same surface of the wafer.

The insulating structure can have a trench structure with a dielectric and a conductor structure with a semiconductor material. The trench structure here can be formed by one or more trenches of any desired shape. Also, the conductor structure can have one or more conductors of any desired shape within the lateral insulating structure. The trench structure here has silicon dioxide or silicon nitride as a dielectric, for example. The cross-section of a trench of the trench structure can have a vertical, inclined or rounded trench wall, for example. The cross-section of the conductor can have a vertical, inclined or rounded conductor wall, for example. A design of the cross-section of the conductor preferably depends on a design of the cross-section of the trench.

The trench structure can border on the buried insulating layer, so that preferably no significant leakage current can flow below the trench structure. This can be achieved, for example, by the means that a bottom of the trench structure is oxidized until an oxide reaches the oxidation of the buried insulating layer. Another option is to etch the trench structure down to the depth of the buried layer, for example.

The conductor structure is designed for conductively connecting the first region to the second region. Consequently, the conductor structure is not interrupted by an insulator such as, e.g., a dielectric. The resistance between the first and second regions is thus preferably defined by the conductor structure. The total resistance of the conductor structure preferably determines the leakage current through the insulating structure. Consequently, the insulating structure is advantageously designed with a high resistance. Said insulating structure preferably has a higher conductivity than the trench structure.

According to an embodiment, the trench structure and the conductor structure are designed geometrically such that a voltage dropping across a trench of the trench structure is lower than an insulation voltage between the first and second regions. The transverse extent of each trench is advantageously subjected to only a portion of the insulation voltage, so that the properties of the trench, such as its thickness or the type of the dielectric, are matched to this portion of the insulation voltage.

The conductor structure can have substantially the same semiconductor material as in the first and/or second region. The conductor structure can be made of silicon. In another embodiment, provision is made for the semiconductor material of the conductor structure to be monocrystalline. To this end, the conductor structure can be structured from monocrystalline semiconductor material by the use of a masking and an etching step. The conductor structure and the first region and the second region are advantageously made from a single layer of monocrystalline semiconductor material such as <100> silicon or silicon carbide.

The conductivity is established by a doping of the semiconductor material of the conductor structure. According to a preferred embodiment, the semiconductor material has a dopant concentration of less than 10¹⁵ (per cm³) as an alternative to intrinsic semiconductor material. A substrate with the appropriate dopant concentration can be used. Alternatively, the dopants can also be introduced by implantation and/or diffusion and/or in situ during an epitaxy process. The dopant concentration is preferably 7×10¹⁴ (per cm³).

Provision is preferably made that the semiconductor material has no pn junction that is operated in the reverse direction upon application of an insulation voltage. In this context, a pn junction has a first region with dopants of a first conductivity type and has a second region with dopants of a second conductivity type. When the pn junction is operated in the forward direction, it has no insulating action. Pn junctions operated in the reverse direction require a large chip area to accommodate a large reverse voltage, which leads to increased costs.

According to an embodiment, the first region can be completely enclosed laterally by the insulating structure. This has the result that the first region is insulated in all lateral directions, and that components advantageously arranged around the first region and the insulating structure are not destroyed by voltages arising in the first region. In addition to the trench structure, the conductor structure advantageously also borders on the buried insulating layer at least in sections.

In another embodiment, provision is made for the trench structure and/or the conductor structure to be designed in the form of a spiral. Accordingly, the trench structure and/or the conductor structure advantageously completely surround the first region with a spiral. The insulating voltage here acts between the outer end and the inner end of the spiral. As a function of the number of turns of the spiral, only a portion of the insulation voltage drops transversely across a trench of the trench structure. The spiral can have a basic shape that is essentially round, oval or rectangular.

According to another embodiment, a number of trenches of the trench structure and/or a number of conductors of the conductor structure are designed with a closed form. The trenches and conductors are preferably arranged so they are nested within one another. The individual conductors are preferably connected to one another in that two conductors adjoin one another or are connected to one another at one point in an advantageous manner. The trenches of the trench structure and/or the conductors of the conductor structure can surround the first region in a ring-shaped, oval and/or rectangular shape.

In another embodiment, the conductor structure can have a connecting structure which connects two conductors with one another in an electrically conductive fashion. The connecting structure can advantageously have polycrystalline semiconductor material, a metal, and/or a silicide. For example, a metallization level of the integrated circuit can be used to form the conductor structure. It is also possible to tap off component voltages by this means.

Another object of the invention is to provide a method for producing a semiconductor arrangement that has a further developed insulating structure.

Accordingly, a method for producing a semiconductor arrangement with components of an integrated circuit is provided. Preferably a wafer is produced with an insulating layer buried under a semiconductor region for vertical insulation. An insulating structure for laterally insulating a first region of the semiconductor region from a second region of the semiconductor region is formed. Advantageously, a high-voltage component, especially an IGBT or a DMOS transistor, is formed in the first region.

To create the insulating structure, a trench structure is etched in the semiconductor to the insulating layer in such a manner that a conductor structure that connects the first region and the second region in an electrically conductive manner is formed from semiconductor material of the semiconductor region. In addition, a dielectric is introduced into the trench structure in order to create the insulating structure. The dielectric preferably covers at least the wall region of the trench structure. The trench structure can then be filled with polysilicon. Alternatively, it is also possible to completely fill it with dielectric. Deposition can be used to introduce the dielectric. Alternatively, it is also possible to oxidize the walls of the trench structure.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic view of a semiconductor arrangement with an insulating structure according to a first exemplary embodiment;

FIG. 2 is a schematic equivalent circuit diagram of the insulating structure from FIG. 1;

FIG. 3 is a schematic sectional view of the semiconductor arrangement from FIG. 1 with the insulating structure;

FIG. 4 is a schematic view of a semiconductor arrangement with an insulating structure of a second exemplary embodiment; and

FIG. 5 is a schematic sectional view of the insulating structure from FIG. 4.

### DETAILED DESCRIPTION

A top view of an insulating structure 1 in a first exemplary embodiment is shown in FIG. 1. The insulating structure 1 has a plurality of trenches 21, 22, 23, 29 filled with dielectric. Four trenches are shown in the exemplary embodiment from FIG. 1. The number of trenches 21, 22, 23, 29 needed in this context depends on the desired insulating voltage which drops across all trenches 21, 22, 23, 29 as a whole. Additional trenches are indicated by dots. The trenches 21, 22, 23, 29 of the insulating structure 1 are designed in a rectangular shape about the component region 10 requiring insulation, with the rectangular trenches 21, 22, 23, 29 being arranged such that they are nested within one another. Together, the trenches 21, 22, 23, 29 constitute a trench structure.

Arranged between the trenches 21, 22, 23, 29 are conductors 31, 32, 33, 39, which have a significantly higher conductivity than the dielectric of the trenches. The conductivity is greater than that of the dielectric by a factor of 106, for example. The conductors 31, 32, 33, 39 here are likewise designed with a rectangular shape, and are are made of monocrystalline silicon that is doped and has a dopant concentration of 7×10¹⁴ (per cm³). The resistivity of the silicon conductors 31, 32, 33, 39 is 20 ohm cm in the exemplary embodiment from FIG. 1.

If the area of the component requiring insulation in the region 10 is approximately 1 mm², a resistance of 5*10⁷ ohm per conductor 31, 32, 33, 39 can be produced. As a result, a leakage current of approximately 2 μA flows through the insulating structure 1 from FIG. 1 in the case of 1000 V insulation voltage with ten trenches 21, 22, 23, 29 and ten conductors 31, 32, 33, 39. The width of the insulating structure 1 is approximately 30 μm. The width of the insulating structure 1 in FIG. 1 is reduced significantly as compared to the width of an alternative insulating pn junction operated in the reverse direction. Each conductor 31, 32, 33, 39 in the exemplary embodiment of FIG. 1 is either exclusively n-doped or exclusively p-doped, so that no pn junction is formed.

Each pair of conductors 31, 32, 33, 39 is conductively connected together by a connecting structure 41, 42, 43, 49, wherein the connecting structure 41, 42, 43, 49 can have monocrystalline, amorphous, or polycrystalline semiconductor material and/or a metal and/or a silicide. The conductors 31, 32, 33, 39 and the connecting structures 41, 42, 43, 49 form a conductor structure. The conductor structure here is designed such that the conductor structure defines the leakage current through the insulating structure. In this context, a leakage current through the trenches 21, 22, 23, 29 can be ignored, since the trenches have a significantly higher resistance than the conductor structure, and since a trench insulation voltage V₁, V₂, V₃ of no more than 100 V is present across each 800 nm wide trench 21, 22, 23, 29. If the insulating structure is to withstand 1000 V of insulation voltage, this will require ten trenches.

Permanent damage to each dielectric-filled trench 21, 22, 23, 29 is prevented in this way. The insulating effect of the trenches 21, 22, 23, 29 is additive, since they are nested within one another. If the conductors 31, 32, 33, 39 were not connected to both potentials of the applied insulation voltage by the connecting structures 41, 42, 43, 49, an accumulation of charge in the conductors 31, 32, 33, 39 would occur as a result of tunneling currents. This accumulation of charge would prevent a uniform voltage drop across the trenches 21, 22, 23, 29, so that one trench would be subjected to a destructive trench insulation voltage. In the example embodiment shown in FIG. 1, charging is prevented by the connecting structures 41, 42, 43, 49 in that the charge carriers can flow away through these connecting structures 41, 42, 43, 49.

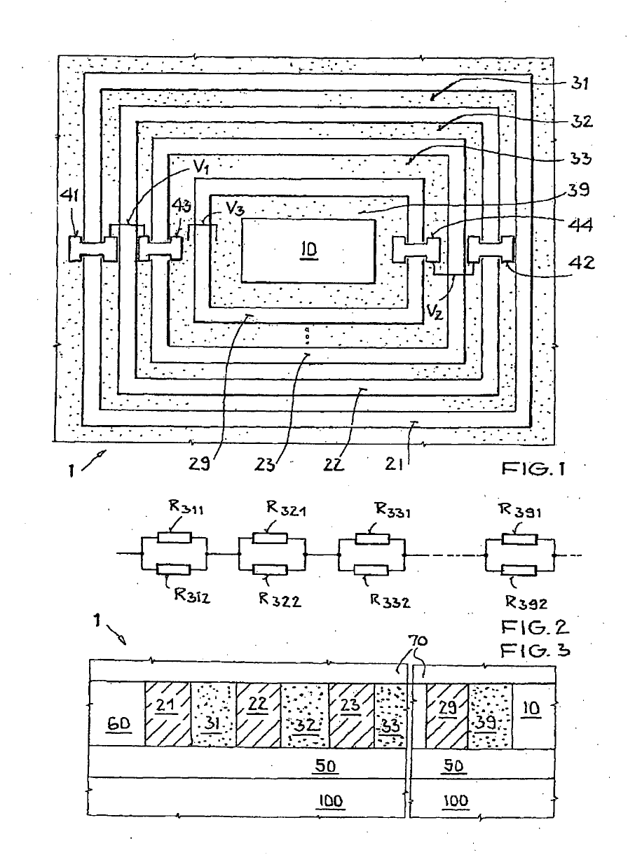

To give the insulating structure a high resistance, the conductors 31, 32, 33, 39 are used as high-value resistors, which together with the connecting structures 41, 42, 43, 49 form a high-value overall resistance. To this end, the conductors 31, 32, 33, 39 are connected at their opposite ends by means of the connecting structures 41, 42, 43, 49. The overall resistance is shown schematically in FIG. 2 as an equivalent schematic. The individual conductors 31, 32, 33, 39 each constitute two parallel-connected resistors R311∥R312, R321∥R322, R331∥R332 and R391∥R392. These parallel connections are all connected in series in order to increase the resistance and to reduce the leakage current through the insulating structure 1.

FIG. 3 schematically shows a cross-sectional representation of the insulating structure 1 from FIG. 1. A buried insulating layer 50, for example of silicon dioxide, is applied to a substrate 100, for example of monocrystalline silicon. Formed above this buried insulating layer 50 are regions 10 and 60 for semiconductor components, which are made of monocrystalline semiconductor material, such as silicon or gallium arsenide, in order to form the components. In order to simplify the drawing, the components in the regions 10 and 60 are not illustrated.

The insulating structure 1 insulates the region 10 from the region 60 by the number of trenches 21, 22, 23, 29 and the number of conductors 31, 32, 33, 39. The dielectric in the trenches 21, 22, 23, 29 borders on the buried insulating layer 50, so that the regions 10, 60 and also the conductors 31, 32, 33, 39 are insulated from the substrate 100. As a result, there is no conductive connection between the regions 10 and 60 through the substrate 100. In addition, the conductor structure is advantageously covered by a passivation layer 70 made of a dielectric, such as BPSG (borophosphosilicate glass).

This semiconductor arrangement as shown in FIGS. 1 through 3 serves, for example, to insulate an IGBT or DMOS transistor, which is formed in the region 10, from a low-voltage circuit integrated on the same semiconductor chip which is formed in the region 60 and is insulated from the IGBT or DMOS transistor by the insulating structure 1. For example, the IGBT must switch a voltage of 700 V, whereas the low-voltage circuit has digital logic.

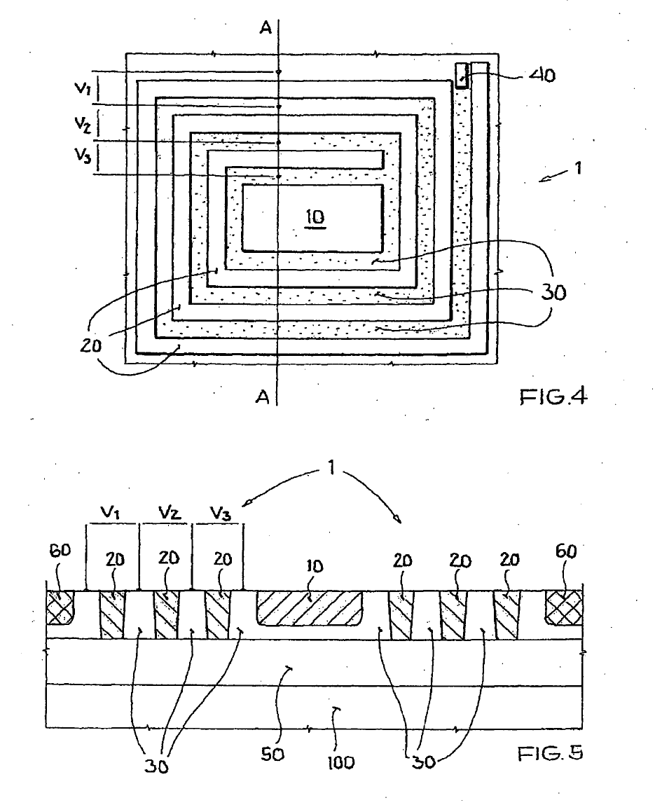

In FIGS. 4 and 5, a different exemplary embodiment is shown in which a single trench 20 and a single conductor 30 are designed in the shape of a spiral to form an insulating structure 1. The insulating structure 1, in turn, insulates the region 10. The conductor 20 of the insulating structure 1 is conductively connected to the region 10 and has a terminal 40. The spiral in FIG. 4 has three turns. The number of turns in the spiral should be adapted depending on the desired insulating voltage of the insulating structure 1. In turn, only a component voltage V₁, V₂, V₃ of the insulating voltage drops across each subregion of the trench 20.

FIG. 5 shows a sectional view along the section line A-A from FIG. 4. The first region 10 is completely surrounded by the insulating structure 1. The second region 60 with additional components is formed outside the insulating structure 1.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A semiconductor arrangement comprising:
a first region in which a number of components are formed;
a second region;
a buried insulating layer for vertically insulating the first region; and
an insulating structure, which is formed between the first region and the second region for laterally insulating the first region from the second region,
wherein the insulating structure includes a trench structure with a dielectric, and a conductor structure with a semiconductor material,
wherein the trench structure borders on the buried insulating layer, and
wherein the conductor structure conductively connects the first region to the second region.

2. The semiconductor arrangement according to claim 1, wherein the trench structure and the conductor structure are geometrically designed such that a voltage dropping across a trench is lower than an insulation voltage between the first region and the second region.

3. The semiconductor arrangement according to claim 1, wherein the semiconductor material is monocrystalline.

4. The semiconductor arrangement according to claim 1, wherein the semiconductor material has a dopant concentration of less than 10¹⁵ (per cm³).

5. The semiconductor arrangement according to claim 1, wherein the semiconductor material has silicon or silicon carbide.

6. The semiconductor arrangement according to claim 1, wherein the semiconductor material has no pn junction that is operated in the reverse direction upon application of an insulation voltage.

7. The semiconductor arrangement according to claim 1, wherein the first region is completely enclosed laterally by the insulating structure.

8. The semiconductor arrangement according to claim 1, wherein the conductor structure borders on the buried insulating layer, at least in sections.

9. The semiconductor arrangement according to claim 1, wherein the trench structure and/or the conductor structure is designed in the form of a spiral.

10. The semiconductor arrangement according to claim 1, wherein a plurality of trenches of the trench structure and/or a plurality of conductors of the conductor structure are designed with a closed form and are arranged to be nested within one another.

11. The semiconductor arrangement according to claim 10, wherein the trenches of the trench structure and/or the conductors of the conductor structure surround the first region in the form of a ring, oval, and/or rectangle.

12. The semiconductor arrangement according to claim 10, wherein the conductor structure has a connecting structure, which connects two conductors with one another in an electrically conductive fashion.

13. The semiconductor arrangement according to claim 12, wherein the connecting structure has polycrystalline semiconductor material.

14. The semiconductor arrangement according to claim 12, wherein the connecting structure has a metal and/or a silicide.

15. The semiconductor arrangement according to claim 1, wherein the conductor structure is covered by a passivation layer, which has a dielectric.

16. The semiconductor arrangement according to claim 1, wherein the semiconductor arrangement insulates an IGBT or DMOS transistor from a low-voltage circuit integrated on the same semiconductor chip.

17. A method for producing a semiconductor arrangement with components of an integrated circuit, the method comprising:
producing a wafer with an insulating layer buried under a semiconductor region for vertical insulation;
forming an insulating structure for laterally insulating a first region of the semiconductor region from a second region of the semiconductor region; and
forming a high-voltage component, an IGBT, or a DMOS transistor in the first region;
wherein, in order to create the insulating structure:
a trench structure is etched in the semiconductor towards the insulating layer in such a manner that a conductor structure, which connects the first region and the second region in an electrically conductive manner, is formed from semiconductor material of the semiconductor region, and
a dielectric is introduced into the trench structure.
